(19) United States
(12) Patent Application Publication
(10) Pub. No.: US 2008/0315879 A1
(43) Pub. Date: Dec. 25, 2008

(54) SYSTEM AND APPARATUS FOR ELECTROMAGNETIC NOISE DETECTION IN AN MR IMAGING SCANNER ENVIRONMENT

(75) Inventor: Saikat Saha, Florence, SC (US)

Correspondence Address: PETER VOGEL;GE HEALTHCARE, 20225 WATER TOWER BLVD., MAIL STOP W492, BROOKFIELD, WI, 53045, US

(73) Assignee: GENERAL ELECTRIC COMPANY, Schenectady, NY (US)

(21) Appl. No.: 11/764,889

(22) Filed: Jun. 19, 2007

(51) Int. Cl. G01R 33/28

(52) U.S. Cl. 324/318

(57) ABSTRACT

A system for detecting electromagnetic noise in a magnetic resonance imaging (MRI) scanner environment includes an antenna configured to detect electromagnetic noise. The antenna includes a first conducting loop and a second conducting loop oriented perpendicularly to the first conducting loop. The system also includes a noise correction system coupled to the antenna and configured to receive noise signals from the antenna.

### FIELD OF THE INVENTION

The present invention relates generally to magnetic resonance imaging (MRI) systems and in particular, to a system and apparatus for detecting electromagnetic noise in an MRI scanner environment.

### BACKGROUND OF THE INVENTION

Magnetic resonance imaging (MRI) is a medical imaging modality that can create images of the inside of a human body without using x-rays or other ionizing radiation. MRI uses a powerful magnet to create a strong, uniform, static magnetic field (i.e., the “main magnetic field”). When a human body, or a part of a human body, is placed in the main magnetic field, the nuclear spins that are associated with the hydrogen nuclei in tissue water become polarized. This means that the magnetic moments that are associated with these spins become preferentially aligned along the direction of the main magnetic field, resulting in a small net tissue magnetization along that axis (the “z axis,” by convention). An MRI system also comprises components called gradient coils that produce smaller amplitude, spatially varying magnetic fields when a current is applied to them. Typically, gradient coils are designed to produce a magnetic field component that is aligned along the z axis, and that varies linearly in amplitude with position along one of the x, y or z axes. The effect of a gradient coil is to create a small ramp on the magnetic field strength, and concomitantly on the resonant frequency of the nuclear spins, along a single axis. Three gradient coils with orthogonal axes are used to “spatially encode” the MR signal by creating a signature resonance frequency at each location in the body. Radio frequency (RF) coils are used to create pulses of RF energy at or near the resonance frequency of the hydrogen nuclei. The RF coils are used to add energy to the nuclear spin system in a controlled fashion. As the nuclear spins then relax back to their rest energy state, they give up energy in the form of an RF signal. The RF signal is detected by the MRI system (e.g., via the RF coils) and is transformed into an image using a computer and known reconstruction algorithms.

During an MRI scan, electromagnetic noise or “spike noise” may be generated inside the scan room. There may be multiple sources of spike noise in the scan room such as, for example, electrostatic discharge (ESD), voltage breakdown between conductors of a gradient coil of the MRI system, metal-on-metal vibration or contact, breaks or varying contact between electrical connections, etc. Receiver coils (e.g., RF coils) in the MRI system are sensitive to the RF signals generated by the patient as well as undesired RF energy such as spike noise. Spike noise in the scan room that is detected by the receiver coils may lead to “white pixel” artifacts in an image or to possible damage to the imaging hardware. A “white pixel” is an effect in k-space that may produce an artifact in the reconstructed MR image making an image undesirable and difficult to interpret. In addition, spike noise generated in a scan room during an MRI scan may induce an overvoltage condition in the receiver path (e.g., the receiver coil(s), preamplifier and other relevant hardware) that may cause damage to the imaging hardware.

Various methods and systems have been developed to detect and correct for spike noise in a scan room. Such systems may utilize an antenna that is positioned inside the scan room to detect spike noise originating inside the scan room. Typically, the antenna (or noise detector) is a single loop (1-Loop) antenna. The operation of a single loop antenna, however, is dependent on direction. Spike noise, however, is generally random in direction and, therefore, a single loop antenna may not detect all of the spike noise in the scan room environment. It would be desirable, therefore, to provide a system and apparatus for detecting electromagnetic noise (e.g., spike noise) in a MRI scanner environment that is less dependent on direction and that is more efficient in detecting all of the electromagnetic noise.

### BRIEF DESCRIPTION OF THE INVENTION

In accordance with an embodiment, a system for detecting electromagnetic noise in a magnetic resonance imaging (MRI) scanner environment includes an antenna configured to detect electromagnetic noise, the antenna including a first conducting loop and a second conducting loop oriented perpendicularly to the first conducting loop. The system further includes a noise correction system coupled to the antenna and configured to receive noise signals from the antenna.

In accordance with another embodiment, a magnetic resonance imaging (MRI) system including a magnetic resonance imaging assembly configured to obtain a set of magnetic resonance (MR) data for a region of interest of a subject and an antenna coupled to the magnetic resonance imaging assembly and configured to detect electromagnetic noise. The antenna includes a first conducting loop and a second conducting loop oriented perpendicularly to the first conducting loop.

### BRIEF DESCRIPTION OF THE DRAWINGS

The invention will become more fully understood from the following detailed description, taken in conjunction with the accompanying drawings, in which:

FIG. 1 is a schematic block diagram of a magnetic resonance imaging system including a noise detector in accordance with an embodiment.

FIG. 2 is a simplified schematic block diagram of a receiver path of an MRI system in accordance with an embodiment.

FIG. 3 is a schematic drawing of a two-loop noise detection antenna in accordance with an embodiment.

### DETAILED DESCRIPTION

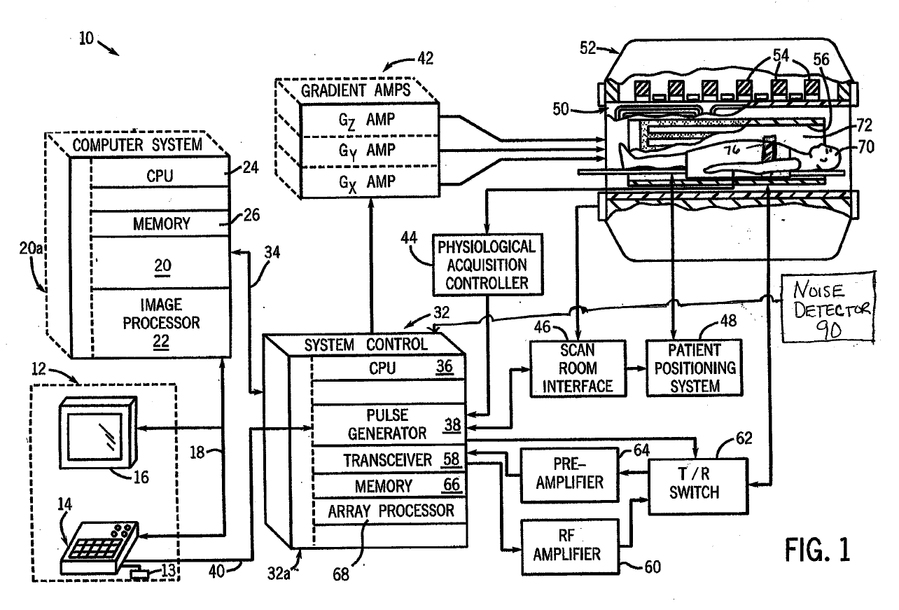

FIG. 1 is a schematic block diagram of an exemplary magnetic resonance imaging system in accordance with an embodiment. The operation of MRI system 10 is controlled from an operator console 12 that includes a keyboard or other input device 13, a control panel 14, and a display 16. The console 12 communicates through a link 18 with a computer system 20 and provides an interface for an operator to prescribe MRI scans, display the resultant images, perform image processing on the images, and archive data and images. The computer system 20 includes a number of modules that communicate with each other through electrical and/or data connections, for example such as are provided by using a backplane 20a. Data connections may be direct-wired links or may be fiber optic connections or wireless communication links or the like. These modules include an image processor module 22, a CPU module 24 and a memory module 26 which may include a frame buffer for storing image data arrays. In an alternative embodiment, the image processor module 22 may be replaced by image processing functionality on the CPU module 24. The computer system 20 is linked to archival media devices, permanent or back-up memory storage or a network. Computer system 20 may also communicate with a separate system control computer 32 through a link 34. The input device 13 can include a mouse, joystick, keyboard, track ball, touch activated screen, light wand, voice control, or any similar or equivalent input device, and may be used for interactive geometry prescription.

The system control computer 32 includes a set of modules in communication with each other via electrical and/or data connections 32a. Data connections 32a may be direct wired links, or may be fiberoptic connections or wireless communication links or the like. In alternative embodiments, the modules of computer system 20 and system control computer 32 may be implemented on the same computer systems or a plurality of computer systems. The modules of system control computer 32 include a CPU module 36 and a pulse generator module 38 that connects to the operator console 12 through a communications link 40. The pulse generator module 38 may alternatively be integrated into the scanner equipment (e.g., magnet assembly 52). It is through link 40 that the system control computer 32 receives commands from the operator to indicate the scan sequence that is to be performed. The pulse generator module 38 operates the system components that play out (i.e., perform) the desired pulse sequence by sending instructions commands and/or requests (e.g., radio frequency (RF) waveforms) describing the timing, strength and shape of the RF pulses and pulse sequences to be produced and the timing and length of the data acquisition window. The pulse generator module 38 connects to a gradient amplifier system 42 and produces data called gradient waveforms which control the timing and shape of the gradient pulses that are to be used during the scan. The pulse generator module 38 may also receive patient data from a physiological acquisition controller 44 that receives signals from a number of different sensors connected to the patient, such as ECG signals from electrodes attached to the patient. The pulse generator module 38 connects to a scan room interface circuit 46 that receives signals from various sensors associated with the condition of the patient and the magnet system. It is also through the scan room interface circuit 46 that a patient positioning system 48 receives commands to move the patient table to the desired position for the scan.

The gradient waveforms produced by the pulse generator module 38 are applied to gradient amplifier system 42 which is comprised of Gx, Gy and Gz amplifiers. Each gradient amplifier excites a corresponding physical gradient coil in a gradient coil assembly generally designated 50 to produce the magnetic field gradient pulses used for spatially encoding acquired signals. The gradient coil assembly 50 forms part of a magnet assembly 52 that includes a polarizing magnet 54 and may include a whole-body RF coil 56, surface or parallel imaging coils 76 or both. The coils 56, 76 of the RF coil assembly may be configured for both transmitting and receiving or for transmit-only or receive-only. A patient or imaging subject 70 may be positioned within a cylindrical patient imaging volume 72 of the magnet assembly 52. A transceiver module 58 in the system control computer 32 produces pulses that are amplified by an RF amplifier 60 and coupled to the RF coils 56, 76 by a transmit/receive switch 62. The resulting signals emitted by the excited nuclei in the patient may be sensed by the same RF coil 56 and coupled through the transmit/receive switch 62 to a preamplifier 64. Alternatively, the signals emitted by the excited nuclei may be sensed by separate receive coils, such as parallel coils or surface coils 76. The amplified MR signals are demodulated, filtered and digitized in the receiver section of the transceiver 58. The transmit/receive switch 62 is controlled by a signal from the pulse generator module 38 to electrically connect the RF amplifier 60 to the RF coil 56 during the transmit mode and to connect the preamplifier 64 to the RF coil 56 during the receive mode. The transmit/receive switch 62 can also enable a separate RF coil (for example, a parallel or surface coil 76) to be used in either the transmit or receive mode.

The MR signals sensed by the RF coil 56 are digitized by the transceiver module 58 and transferred to a memory module 66 in the system control computer 32. Typically, frames of data corresponding to MR signals are stored temporarily in the memory module 66 until they are subsequently transformed to create images. An array processor 68 uses a known transformation method, most commonly a Fourier transform, to create images from the MR signals. These images are communicated through the link 34 to the computer system 20 where it is stored in memory. In response to commands received from the operator console 12, this image data may be archived in long-term storage or it may be further processed by the image processor 22 and conveyed to the operator console 12 and presented on display 16.

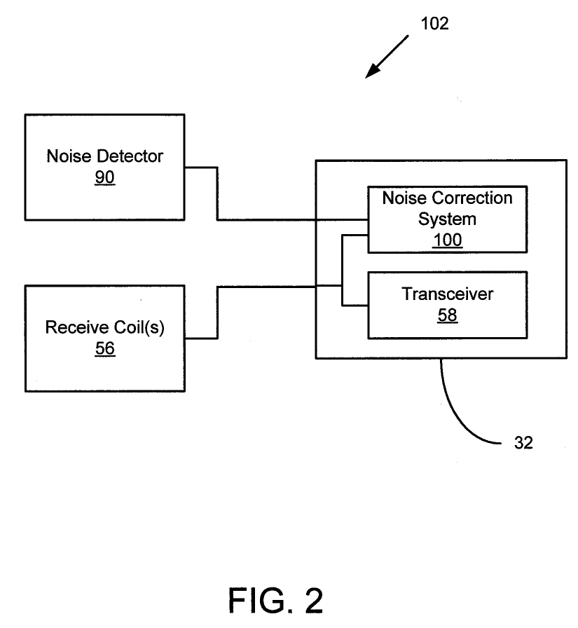

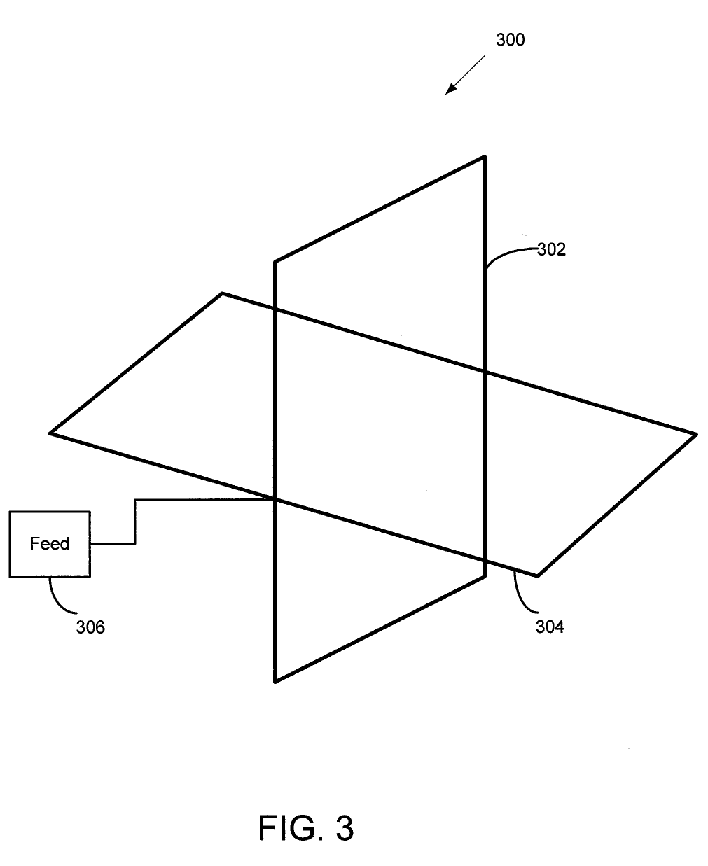

A noise detector 90 is positioned in a scan room (or magnet room) or scanner environment in proximity to the magnet assembly 52. Noise detector 90 is coupled to system control computer 32, for example, to transceiver 58 in the receiver path. Noise detector 90 is a two-loop antenna configured to detect electromagnetic noise (e.g., spike noise) in the scan room as discussed further below with respect to FIGS. 2 and 3. The noise detector 90 shown in FIGS. 2 and 3 may be used with the above-described MRI system of FIG. 1 or any similar or equivalent system for obtaining MR images.

FIG. 2 is a simplified schematic block diagram of a receiver path 102 of an MRI system in accordance with an embodiment. In FIG. 2, a noise detector 90 is coupled to a noise correction system 100 in, for example, a system control computer 32. Noise detector 90 is configured to detect electromagnetic noise in a scan room or scanner environment housing a magnet assembly (not shown in FIG. 2). As mentioned, noise detector 90 is a two-loop antenna. FIG. 3 is a schematic drawing of a two-loop noise detection antenna in accordance with an embodiment. In FIG. 3, a two-loop antenna 300 includes a first conducting loop 302 and a second conducting loop 304. First conducting loop 302 is positioned perpendicular to the second conducting loop 304. The perpendicular orientation of the first conducting loop 302 and the second conducting loop 304 results in less interaction between the first conducting loop 302 and the second conducting loop 304. First conducting loop 302 and second conducting loop 304 may have a single feed 306. Antenna 300 is configured to provide both an azimuthal gain, Φ_{GAIN} (where Φ is the azimuthal angle measured from the x-axis), and an elevational gain, θ_{GAIN} (where θ is the elevational angle measured from the z-axis). Accordingly, antenna 300 may detect electromagnetic noise in a plurality of directions. Electromagnetic noise (or spike noise) is typically random in direction. In one embodiment, antenna 300 may be tuned to a particular frequency of operation using, for example, non-magnetic trimmer capacitors (not shown).

Returning to FIG. 2, the electromagnetic noise signals detected by noise detector 90 are provided to the noise correction system 100 for processing. Noise correction system 100 may use known methods for removing or compensating for noise signals. Alternatively, noise correction system 100 may be a transient noise suppression (TNS) system. A receive coil (or coils) 56 is also coupled to system control computer 32. Various other elements that may be included in the receiver path 102, such as amplifiers, a transmit/receive switch, etc., are omitted from FIG. 2 for clarity.

Receive coil(s) 56 sense the signals emitted by the subject in response to the application of magnetic field gradients and RF excitation pulses. Receive coil 56 may be a single coil or multiple coils including, but not limited to, an RF body coil, parallel coils, surface coils, a phase-array coil architecture, a head coil and the like. Receiver coil(s) 56 may be coupled to the noise correction system 100, a transceiver 58 or both. In one embodiment, the noise correction system 100 is incorporated in the transceiver 58. The signals induced in the receiver coil(s) 56 are transmitted to the transceiver 58 (e.g., a receiver channel or channels of the transceiver 58) to be processed, for example, to be demodulated, filtered and digitized. In an embodiment, the signals detected by the receiver coil or coils 56 are also provided to the noise correction system 100 to be used in correcting or compensating for electromagnetic noise detected by noise detector 90.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

Many other changes and modifications may be made to the present invention without departing from the spirit thereof. The scope of these and other changes will become apparent from the appended claims.

What is claimed is:

1. A system for detecting electromagnetic noise in a magnetic resonance imaging (MRI) scanner environment, the system comprising:
an antenna configured to detect electromagnetic noise, the antenna comprising:
a first conducting loop; and
a second conducting loop oriented perpendicularly to the first conducting
loop; and
a noise correction system coupled to the antenna and configured to receive noise signals from the antenna.

2. A system according to claim 1, wherein the noise correction system is configured to compensate for the noise signals.

3. A system according to claim 1, wherein the noise correction system is a transient noise suppression system.

4. A system according to claim 1, wherein the antenna is configured to detect electromagnetic noise in a plurality of directions.

5. A system according to claim 1, wherein the antenna further comprises a single feed.

6. A magnetic resonance imaging (MRI) system comprising:
a magnetic resonance imaging assembly configured to obtain a set of magnetic resonance (MR) data for a region of interest of a subject; and
an antenna coupled to the magnetic resonance imaging assembly and configured to detect electromagnetic noise, the antenna comprising:
a first conducting loop; and
a second conducting loop oriented perpendicularly to the first conducting loop.

7. A MRI system according to claim 6, wherein the antenna is positioned in proximity to the magnetic resonance imaging assembly.

8. A MRI system according to claim 6, wherein the magnetic resonance imaging assembly comprises a noise correction processor configured to receive noise signals from the antenna.

9. A MRI system according to claim 8, wherein the noise correction processor is a transient noise suppression system.

10. A MRI system according to claim 6, wherein the antenna is configured to detect electromagnetic noise in a plurality of directions.

11. An MRI system according to claim 8, wherein the noise correction processor is configured to compensate for the noise signals.

12. An MRI system according to claim 6, wherein the antenna further comprises a single feed.
